(19) United States
(12) Patent Application Publication
(10) Pub. No.: US 2010/0156290 A1
(43) Pub. Date: Jun. 24, 2010

(54) Paste composition for electrode, plasma display panel including the electrode, and associated methods

(76) Inventors: Yong Hyun Kim, Uiwang-si (KR); Jae Hwan Oh, Uiwang-si (KR); Sang Hee Park, Uiwang-si (KR); Deok Young Choi, Uiwang-si (KR); Hyun Don Kim, Uiwang-si (KR)

Correspondence Address: LEE & MORSE, P.C., 3141 FAIRVIEW PARK DRIVE, SUITE 500, FALLS CHURCH, VA, 22042, US

(21) Appl. No.: 12/654,289

(22) Filed: Dec. 16, 2009

(30) Foreign Application Priority Data
Dec. 24, 2008 (KR) 10-2008-0133508

(51) Int. Cl. H01J 17/49; H01B 1/12; H01B 1/00; H01B 1/22; B05D 5/12; G03F 7/00

(52) U.S. Cl. 313/582; 252/519.3; 252/500; 252/514; 252/513; 427/77; 430/311

(57) ABSTRACT

A paste composition for an electrode, a PDP including the electrode, and associated methods, the paste composition including a conductive material, a black pigment, a glass frit, and an organic binder, wherein the black pigment includes a magnetic black pigment, the magnetic black pigment being included in an amount of about 0.1 to about 20 wt %, based on the total weight of the composition.

### BACKGROUND

1. Field

Embodiments relate to a paste composition for an electrode, a plasma display panel including the electrode, and associated methods.

2. Description of the Related Art

A plasma display panel (PDP) is an electronic display device that includes front and rear glass substrates facing each other to define a space therebetween. The space may be partitioned by barriers between the front and rear glass substrates and filled with gases, e.g., Ne+Ar, Ne+Xe, or the like, such that light is emitted and images are displayed by application of voltage to positive and negative electrodes.

PDPs may be used in high definition TVs because of their strong non-linearity with respect to applied voltage, long lifetime, high luminance and high light-emission efficiency, wide viewing angle, and large size.

The front glass substrate may have a pair of discharge-sustain electrodes, which extend in parallel to each other in a longitudinal direction. Each electrode may include a transparent electrode and a bus electrode. The discharge sustain-electrode pair may be covered with a transparent dielectric layer and a transparent protective layer. Like the front glass substrate, the rear glass substrate may be covered with a dielectric layer and may have a plurality of address electrodes orthogonal to the discharge sustain-electrode pairs.

Each discharge cell may be formed in a pixel unit by barriers at or near a location between where the pair of discharge sustain-electrodes crosses the address electrodes. Each discharge cell may be selectively discharged to induce phosphors to emit light when displaying images.

The address electrode may be a metallic electrode of the PDP and may be formed of silver paste by, e.g., photolithography, screen printing, offset printing, or the like.

If the transparent electrodes on the front glass substrate are formed of indium tin oxide (ITO), the bus electrode having a multilayer structure and high conductivity may be used, due to large sheet resistance of ITO. In this case, however, since the bus electrode having the multilayer structure may shield emitted light and may reduce luminance, it may be necessary to reduce the width of the bus electrode.

Such a bus electrode may be formed in a Cr/Cu/Cr triple-layer structure by, e.g., vacuum deposition and etching. However, a process of forming a bus electrode having a Cr/Cu/Cr triple-layer structure by vacuum deposition may require long process time, may increase manufacturing costs due to an expensive thin-film fabrication apparatus and expensive materials, and may cause environmental pollution relating to etching.

The bus electrode may also have a single layer structure exhibiting properties of both the black layer and the conductive layer. However, increasing blackness of a single-layer electrode by adding a black material may yield an electrode having high resistance. Further, adding conductive material may reduce blackness, thereby negatively influencing reflected luminance of external light, and contrast of a resultant PDP may be undesirably lowered.

The single-layer integral-type bus electrode may reduce costs associated with processing and materials. However, the black pigment for the bus electrode may have high resistance, thereby causing an increase in resistance of the bus electrode. Thus, a higher amount of conductive material may be required in the bus electrode, thereby reducing the black degree of the bus electrode compared with, e.g., the double-layer bus electrode.

Alternatively, the bus electrode may have a double layer structure including a black layer and a separate conductive layer. The black layer may reduce reflection of external light, thereby enhancing contrast of the display. The bus electrode may be formed by, e.g., a printing process such as screen printing and offset printing, or photolithography.

### SUMMARY

Embodiments are directed to a paste composition for an electrode, a plasma display panel including the electrode, and associated methods, which substantially overcome one or more of the problems due to the limitations and disadvantages of the related art.

It is a feature of an embodiment to provide a paste composition for electrodes, the paste composition including a magnetic black pigment and being capable of realizing an electrode having both superior black degree and electrical conductivity.

It is another feature of an embodiment to provide a method of forming an electrode, in which a magnetic black pigment in the paste composition is moved toward a glass substrate and a magnetic substrate during a drying process of the paste composition to thereby increase a black degree at a lower portion of the electrode while allowing other portions of the electrode to exhibit lower resistance through an electrically conductive material.

At least one of the above and other features and advantages may be realized by providing a paste composition for an electrode including a conductive material, a black pigment, a glass frit, and an organic binder, wherein the black pigment includes a magnetic black pigment, the magnetic black pigment being included in an amount of about 0.1 to about 20 wt %, based on the total weight of the paste composition.

The magnetic black pigment may include a metal oxide including at least one of iron (Fe), boron (B), samarium (Sm), and neodymium (Nd).

The black pigment may further include a second metal oxide, the second metal oxide including at least one of cobalt (Co), manganese (Mn), chromium (Cr), copper (Cu), aluminum (Al), nickel (Ni), zinc (Zn), ruthenium (Ru), and rhodium (Rh).

The second metal oxide may not be magnetic.

The conductive material may be included in an amount of about 30 to about 90 wt %, the glass frit may be included in an amount of about 1 to about 20 wt %, and the organic binder may be included in an amount of about 1 to about 20 wt %, based on the total weight of the paste composition.

The conductive material may include at least one of gold (Au), silver (Ag), copper (Cu), nickel (Ni), palladium (Pd), platinum (Pt), aluminum (Al), and alloys thereof, and the organic binder may include at least one of an acrylic polymer and a cellulose polymer.

The paste composition may further include about 1 to about 20 parts by weight of a photo-polymerizable compound and about 0.1 to about 10 parts by weight of a photo-polymerization initiator, based on 100 parts by weight of the paste composition.

The paste composition may further include an additive including at least one of a UV stabilizer, a viscosity stabilizer, a defoamer, a disperser, a leveling agent, an antioxidant agent, and a thermo-polymerization inhibitor.

At least one of the above and other features and advantages may also be realized by providing a method of fabricating an electrode including depositing or printing the paste composition of an embodiment on a glass substrate, positioning the glass substrate on a magnet substrate, and drying the paste composition.

The method may further include forming an electrode pattern by photolithographically developing the dried paste composition.

The paste composition may be deposited on the glass substrate at a thickness of about 5 to about 40 μm.

The drying the paste composition may be performed at about 80 to about 150° C. for about 20 to about 60 minutes.

The method may further include firing the paste composition after drying, and the firing the paste composition may be performed at about 500 to about 600° C.

At least one of the above and other features and advantages may also be realized by providing a plasma display panel including an electrode fabricated by the method of an embodiment.

At least one of the above and other features and advantages may also be realized by providing a plasma display panel including an electrode including a conductive material, a black pigment, and a glass frit, wherein the black pigment includes a magnetic black pigment.

The magnetic black pigment may include a metal oxide including at least one of iron (Fe), boron (B), samarium (Sm), and neodymium (Nd).

The black pigment may further include a second metal oxide, the second metal oxide including at least one of cobalt (Co), manganese (Mn), chromium (Cr), copper (Cu), aluminum (Al), nickel (Ni), zinc (Zn), ruthenium (Ru), and rhodium (Rh).

The plasma display panel may further include a substrate, the electrode may have a monolithic structure having an upper portion and a lower portion, the lower portion being adjacent to the substrate and including a greater proportion of magnetic black pigment, relative to the conductive material, than the upper portion.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a flowchart of a method of forming an electrode according to an embodiment;

FIG. 2 illustrates a schematic view of moving a magnetic black pigment toward a glass substrate during drying of a paste composition; and

FIG. 3 illustrates a flowchart of a method of forming an electrode by photolithography according to an embodiment.

### DETAILED DESCRIPTION

Korean Patent Application No. 10-2008-0133508, filed on Dec. 24, 2008, in the Korean Intellectual Property Office, and entitled: “Paste Composition for Electrode Comprising Magnetic Black Pigment, Method of Fabricating Electrode Using the Paste Composition, and Plasma Display Panel Comprising the Electrode,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Paste Composition for an Electrode

A paste composition for an electrode according to an embodiment may include, e.g., a conductive material, a magnetic black pigment, a glass frit, an organic binder, and a solvent.

Both organic and inorganic conductive materials may be used as the conductive material. The conductive material may be metal powder including, e.g., gold (Au), silver (Ag), copper (Cu), nickel (Ni), palladium (Pd), platinum (Pt), aluminum (Al), and/or alloys thereof. The metal powder may have an average particle diameter of, e.g., about 0.1 to about 3 μm based on a desired film thickness. In another implementation, the conductive material may be an organic material. The conductive material may be non-magnetic.

The conductive material may be included in an amount of, e.g., about 30 to about 90 wt %, based on the total weight of the composition. Maintaining the amount of the conductive material at about 30 wt % or greater may help ensure that the resistance of the electrode does not increase, thereby avoiding an undesirable increase in discharge voltage and luminance deterioration. Maintaining the amount of the conductive material at about 90 wt % or less may help ensure that the amount of the glass frit and organic binder is not comparatively lowered, thereby ensuring ease of forming the paste while also avoiding deterioration of bonding properties of the paste to a glass substrate. In an implementation, the conductive material may be included in an amount of about 50 to about 80 wt %.

The magnetic black pigment may improve the blackness of the electrode. The magnetic black pigment may include, e.g., a magnetic metal oxide including, e.g., iron (Fe), boron (B), samarium (Sm), and/or neodymium (Nd). In an implementation, the magnetic metal oxide may be ferrite.

The magnetic black pigment may be included in an amount of, e.g., about 0.1 to about 20 wt %, based on the total weight of the composition. Maintaining the amount of the magnetic black pigment at about 0.1 wt % or greater may help ensure that the magnetic black pigment provides a noticeable contrast-enhancing effect in a resultant PDP. Maintaining the amount of the magnetic black pigment at about 20 wt % or less may help ensure that the magnetic black pigment does not cause an undesirable increase in resistance of the electrode by reducing the amount of conductive material.

In a process of drying the paste composition, the magnetic black pigment in the paste composition may be caused to move towards a magnet substrate. For example, a glass substrate may be positioned on the magnet substrate. Thus, after the drying process, most of the magnetic black pigment in the electrode layer may be located near the glass substrate, such that a lower portion of the electrode exhibits high blackness. Accordingly, it is possible to realize high blackness with only a small amount of the magnetic black pigment. In addition, since most of the magnetic black pigment may move toward the lower portion of the electrode, the amount of the magnetic black pigment in an upper, conductive portion of the electrode may be reduced. As a result, it is possible to fabricate a single, monolithic electrode that exhibits high conductivity after firing while also having high blackness at the glass substrate. Thus, the lower portion of the electrode, adjacent to the substrate, may include a greater proportion of magnetic black pigment, relative to the conductive material, than the upper portion.

The paste composition may further include another metal oxide, which may not be magnetic. For example, the paste composition may include the magnetic black pigment as well as, e.g., cobalt (Co), manganese (Mn), chromium (Cr), copper (Cu), aluminum (Al), nickel (Ni), zinc (Zn), ruthenium (Ru), and/or rhodium (Rh).

The glass frit may increase adhesion between the conductive material and a glass substrate. The glass frit may have a softening temperature of, e.g., about 300 to about 600° C. The glass frit may be fired at, e.g., about 400 to about 700° C. The glass frit may include, e.g., a lead oxide glass frit, a bismuth oxide glass fit, and/or a zinc oxide glass fit.

The glass frit may be included in an amount of, e.g., about 1 to about 20 wt %, based on the total weight of the composition. Maintaining the amount of the glass frit at about at about 1 wt % or greater may help ensure that adhesion between the conductive material and the glass substrate is not reduced. Maintaining the amount of the glass frit at about 20 wt % or less may help ensure that an excessive amount of the glass frit does not remain after firing, thus avoiding an increase in resistance of the electrode. In an implementation, the glass frit may be included in an amount of about 3 to about 15 wt %.

The organic binder may disperse and bind the conductive material and the glass fit in the paste. The organic binder may also impart bonding properties to the paste with respect to the glass substrate prior to firing.

The organic binder may include, e.g., an acrylic copolymer. In an implementation, the acrylic copolymer may be obtained via copolymerization of acrylic monomers having a hydrophilic component, e.g., carboxyl group and the like, to impart alkali developable properties. The organic binder may include, e.g., a cellulose polymer, such as ethyl cellulose, hydroxyethyl cellulose, hydroxypropyl cellulose, hydroxyethylhydroxypropyl cellulose, and the like.

The organic binder may be included in an amount of, e.g., about 1 to about 20 wt %, based on the total weight of the composition. Maintaining the amount of the organic binder at about 1 wt % or greater may help ensure that the paste does not exhibit significantly low viscosity or a decrease in bonding strength with respect to the glass substrate after drying. Maintaining the amount of the organic binder at about 20 wt % or less may help ensure that an excessive amount of the organic binder does not remain and after firing, thus avoiding an increase in resistance of the electrode. In an implementation, the organic binder may be included in an amount of about 3 to about 15 wt %.

The solvent may have a boiling point of, e.g., about 120° C., and may include a solvent suitable for the preparation of paste compositions for electrodes, e.g., methyl cellosolve, ethyl cellosolve, butyl cellosolve, aliphatic alcohol, alpha-terpineol, beta-terpineol, dihydro-terpineol, ethylene glycol, ethylene glycol monobutyl ether, butyl cellosolve acetate, and/or texanol.

The amount of the solvent is not specifically limited and the solvent may be added in the balance amount to the composition. For example, the solvent may be included in an amount of about 1 to about 70 wt %, based on the total weight of the composition, depending on the desired viscosity of the paste.

The paste composition may further include, e.g., a photo-polymerizable compound and a photo-polymerization initiator, which may be used when photolithography is used in a method of fabricating an electrode.

The photo-polymerizable compound may be a multi-functional monomer or oligomer suitable for use in a photosensitive resin composition. The photo-polymerizable compound may include, e.g., ethylene glycol diacrylate, triethylene glycol diacrylate, 1,4-butandiol diacrylate, 1,6-hexanediol diacrylate, neopentyl glycol diacrylate, pentaerythritol diacrylate, pentaerythritol triacrylate, dipentaerythritol diacrylate, dipentaerythritol triacrylate, dipentaerythritol pentacrylate, dipentaerythritol hexacrylate, bisphenol-A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butandiol dimethacrylate, and/or 1,6-hexanediol dimethacrylate. In another implementation, the photo-polymerizable compound may include, e.g., trimethylopropane ethoxy triacrylate.

The photo-polymerizable compound may be included in an amount of, e.g., about 1 to about 20 parts by weight, based on 100 parts by weight of the paste composition. Maintaining the amount of the photo-polymerizable compound at about 1 part by weight or greater may help ensure that the paste is sufficiently photo-cured, thus avoiding pattern omission during development. Maintaining the amount of the photo-polymerizable compound at about 20 parts by weight or less may help ensure that an excessive amount of the multifunctional monomer or oligomer does not obstruct decomposition of organic material during firing, thus advantageously reducing the resistance of the electrode.

The photo-polymerization initiator may be a photo-polymerization initiator that exhibits superior photo-reactivity in an ultraviolet wavelength band of, e.g., about 200 to about 400 nm. The photo-polymerization initiator may include, e.g., benzophenone, acetophenone, and/or triazine-based compositions. The photo-polymerization initiator may be included in an amount of, e.g., about 0.1 to about 10 parts by weight, based on 100 parts by weight of the paste composition. Maintaining the amount of the photo-polymerization initiator at about 0.1 parts by weight or greater may help ensure that the paste is sufficiently photo-cured, thus avoiding pattern omission during development. Maintaining the amount of the photo-polymerization initiator at about 10 parts by weight or less may help ensure that resistance of a resultant electrode does not increase due to the presence of non-conductive organic materials reducing the amount of conductive material in the composition.

The paste composition may further include one or more of, e.g., a UV stabilizer, a viscosity stabilizer, a defoamer, a disperser, a leveling agent, an antioxidant agent, a thermo-polymerization inhibitor, and the like.

Electrode Fabrication Method

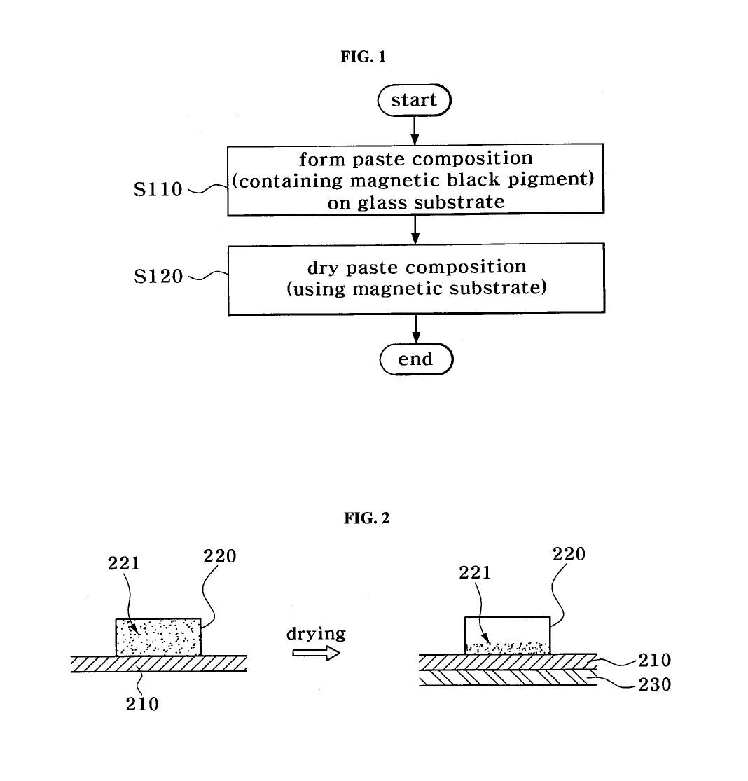

FIG. 1 illustrates a flowchart of a method of forming an electrode according to an embodiment. FIG. 2 illustrates a schematic view moving a magnetic black pigment toward a glass substrate during drying of a paste composition.

Referring to FIGS. 1 and 2, the method according to the present embodiment may include disposing a paste composition 220 on a glass substrate 210 in operation S110 and drying the paste composition 220 in operation S120. The paste composition 220 may be the paste composition for forming an electrode described above. The paste composition may be disposed on the glass substrate by, e.g., screen printing, offset printing, photolithography, and the like.

In operation S110, the paste composition 220 containing a magnetic black pigment 221 according to an embodiment may be formed on the glass substrate 210. The paste composition 220 may include about 0.1 to about 20 wt % magnetic black pigment 221, based on the total weight of the paste composition 220.

If the method is performed by a printing process, e.g., screen printing, offset printing, and the like, operation S110 may be performed by printing. If the method is performed by photolithography, operation S110 may be performed by deposition.

In operation S120, the glass substrate 210 having the paste composition 220 including the magnetic black pigment 221 thereon may be placed on a magnet substrate 230 and then dried. The magnet substrate 230 may include, e.g., one magnet, a plurality of magnets, etc.

While drying the paste composition 220, the magnetic black pigment 221 in the paste composition 220 may be caused to move towards the magnet substrate 230 due to a magnetic attraction of the magnet substrate 230 for the magnetic black pigment. After operation S120, most of the magnetic black pigment 221 may be located near the magnet substrate 230, i.e., on the surface of the glass substrate 210, as illustrated in FIG. 2.

As a result, a lower portion (adjacent the glass substrate) of the resulting electrode may have high blackness with a higher amount of black pigment. Most of the magnetic black pigment may move toward the glass substrate so as not to obstruct firing of the conductive portion, thereby enabling formation of an electrode having superior conductivity in an upper portion thereof after firing.

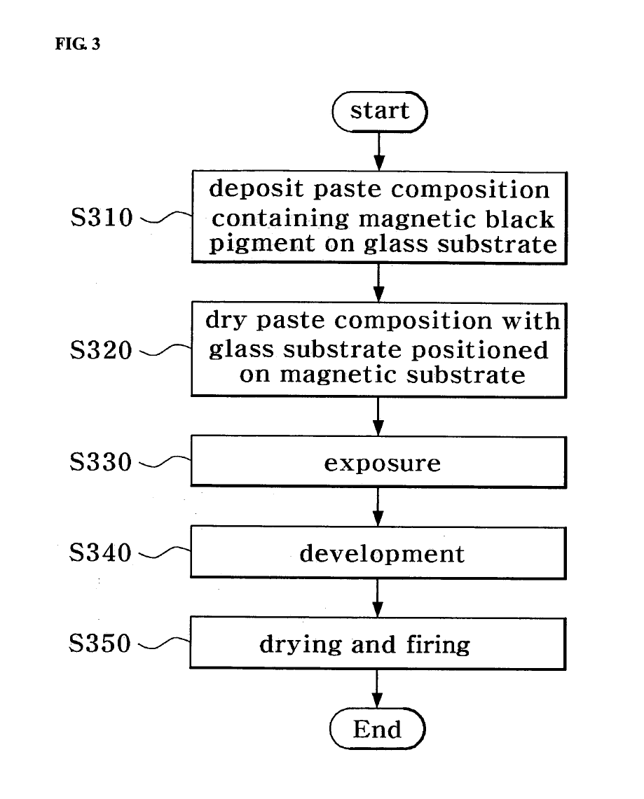

FIG. 3 illustrates a flowchart of a method of forming an electrode by photolithography according to an embodiment. Referring to FIG. 3, the method of forming an electrode by photolithography may be performed as follows.

First, the paste composition containing the magnetic black pigment according to an embodiment may be deposited to a thickness of, e.g., about 5 to about 40 μm, on a glass substrate in operation S310. Then, the glass substrate may be positioned on a magnet substrate. The magnet substrate may be the same as the magnet substrate described above. Then, with the glass substrate on the magnet substrate, or after leaving the glass substrate on the magnet substrate for a predetermined length of time sufficient to migrate the magnetic black pigment, the paste composition may be dried at about 80 to about 150° C. for about 20 to about 60 minutes in operation S320. Next, the dried paste composition may be subjected to an ultraviolet exposure process using a photo mask in operation S330. Then, an exposed region or a non-exposed region may be selectively removed from the exposed paste composition via development in operation S340. Finally, the remaining paste composition may be dried and fired at about 500 to about 600° C. in operation S350.

The electrode fabricated by photolithography, screen printing, or offset printing described above may be used as an electrode for a display such as a PDP, e.g., as a bus electrode or address electrode of the PDP.

The embodiments will be further described with reference to the following examples, but it should be understood that the embodiments are in no way limited to those examples.

### EXAMPLES

### 1. Preparation of Paste Composition

### Example 1

A paste composition was prepared by mixing and stirring 60 g of silver powder (average particle size: 1.5 μm, AG-2-11 available from Dowa Hightech Co., Ltd.) as a conductive material, 5 g of LF7001 (Particlogy Co., Ltd., Korea) as a glass frit, 3 g of ferrite magnetic powder OP-56 (Dowa Hightech Co., Ltd.) as a magnetic black pigment, 7 g of poly(methyl)methacrylate-co-methacrylic acid P-118 (Nippon Gohsei Co., Ltd.) as a binder, and 25 g of texanol (available from Eastman Chemical Co., Ltd., U.S.A.) as a solvent, followed by sufficient dispersion using a 3-roll mill.

### Example 2

A paste composition was prepared with the same components as those of Example 1 except for using a ferrite magnetic powder UZ-94 (Dowa Hightech Co., Ltd.) as the magnetic black pigment.

### Example 3

A paste composition was prepared with the same components as those of Example 1 except for using 2 g of ferrite magnetic powder OP-56 (Dowa Hightech Co., Ltd.) and 1 g of non-magnetic powder CO₃O₄ (Seido Co., Ltd) as a black pigment.

### Example 4

A paste composition was prepared by mixing and stirring 60 g of silver powder (average particle size: 1.5 μm, AG-2-11 available from Dowa Hightech Co., Ltd.) as a conductive material, 5 g of LF7001 (Particlogy Co., Ltd., Korea) as a glass frit, 3 g of ferrite magnetic powder (available from Dowa Hightech Co., Ltd.) as a magnetic black pigment, 6.5 g of poly(methyl)methacrylate-co-methacrylic acid P-118 (Nippon Gohsei Co., Ltd.) as a binder, 4.5 g of trimethylopropane ethoxy triacrylate (available from Miwon Commercial Co., Ltd.), 2 g of 2-methyl-4′-(methylthio)-2-morpholino-propiophenone (available from Sartomer Co., Ltd.) as a photo-polymerization initiator, and 19 g of texanol (available from Eastman Chemical Co., Ltd., U.S.A.) as a solvent, followed by sufficient dispersion using a 3-roll mill.

### Comparative Example 1

A paste composition was prepared with the same components as those of Example 1 except for using 3 g of non-magnetic powder CO₃O₄ (Seido Co., Ltd) as the black pigment, instead of the magnetic black pigment of Example 1.

Table 1 shows compositional ratios of the paste compositions of the Examples and the Comparative Example.

TABLE 1

| | | | Black pigment | | | |
|---|---|---|---|---|---|---|
| | Silver | Glass | | Non- | Organic | |
| | powder | frit | Magnetic | magnetic | binder | Solvent |
| Example 1 | 60 | 5 | 3 | — | 7 | 25 |
| Example 2 | 60 | 5 | 3 | — | 7 | 25 |
| Example 3 | 60 | 5 | 2 | 1 | 7 | 25 |
| Example 4 | 60 | 5 | 3 | — | 6.5 | 19 |
| Comparative | 60 | 5 | — | 3 | 7 | 25 |
| Example 1 | | | | | | |

(units = wt %)

### 2. Measurement Method

Each of the paste compositions of Examples 1 to 4 and Comparative Example 1 was printed on a glass substrate using a printer (printing was used to test all of the Examples 1 to 4, including examples designed for photolithography such as Example 4). The glass substrate was then positioned on a magnet substrate, followed by drying the paste composition at 130° C. for 30 minutes to form an electrode. Then, specific resistance and blackness of the electrode were measured as follows. Table 2 shows the results of the measurement.

Specific Resistance

After measuring resistance of the electrode using a wire-resistance tester, 2000 Multimeter (Keithley Co., Ltd.), line width and thickness of the electrode were measured using a profiler, P-10 (Tencor Co., Ltd.). Then, the specific resistance of the electrode pattern was calculated by the following equation:

Specific resistance(μΩ·cm)=wire resistance(Ω)×thickness(cm)×width (cm)/length(cm)

Here, as the specific resistance is lowered, the wire resistance on a panel is also lowered and discharge voltage decreases, thereby enhancing luminance.

Measurement of Black Degree (L*)

The blackness in terms of (L*) was measured using a color difference meter, CM-508i (Minolta Co., Ltd.).

The (L*) may be from 0 to 100. An (L*) of 100 represents pure white and an (L*) of 0 represents pure black. As the (L*) is lowered, the degree of blackness increases and the color approaches black color. In other words, the lower the (L*), the blacker the material. The blackness of an electrode is a very important factor determining brightness and reflected luminance with respect to external light as well as contrast when forming a pattern of a panel.

### 3. Measurement of Properties

TABLE 2

| | Specific resistance (μΩ · cm) | Blackness (L*) |
|---|---|---|
| Example 1 | 3.0 | 57 |
| Example 2 | 3.2 | 60 |
| Example 3 | 3.6 | 62 |
| Example 4 | 3.6 | 63 |
| Comparative Example 1 | 3.7 | 66 |

As can be seen from Table 2, Examples 1 to 4 using the magnetic black pigments exhibited lower specific resistances and better blacknesses than Comparative Example 1, which contained the non-magnetic black pigment without the magnetic black pigment.

It can be seen from this result that samples prepared using the magnetic black pigment and dried on the magnet substrate realized superior electrical conductivity and blackness.

As is apparent from the above description and examples, an electrode for a PDP prepared using a paste composition including a magnetic black pigment according to an embodiment may have superior properties in terms of blackness (L*), reflected luminance of external light, and electrical conductivity.

In contrast, when forming a typical bus electrode having a double layer structure by, e.g., photolithography, a printing/drying process may be performed twice in order to form two electrode layers, i.e., a black layer and a conductive layer. Further, non-uniformity between the two layers may cause electrode defects.

Because a bus electrode formed on the front glass substrate by photolithography may reduce luminance by blocking light emitted through the front glass substrate, it may be necessary for the bus electrode to have a narrow width. Further, the black layer of the double-layer structure may be formed of a conductive metal oxide, which may have a much higher resistance than the conductive layer and may be very expensive. Moreover, the separate double-layer structure may require repetition of the printing/drying process.

Exemplary embodiments have been disclosed herein, and although specific terms are employed, they are used and are to be interpreted in a generic and descriptive sense only and not for purpose of limitation. For example, although example embodiments describe electrodes of a PDP, it will be understood that electrodes may be formed in other displays in which enhanced contrast may be advantageous, e.g., field emission displays (FED), surface conduction electron emitter displays (SED), etc. Accordingly, it will be understood by those of ordinary skill in the art that various changes in form and details may be made without departing from the spirit and scope of the present invention as set forth in the following claims.

What is claimed is:

1. A paste composition for an electrode, comprising:
a conductive material;
a black pigment;
a glass frit; and
an organic binder,
wherein the black pigment includes a magnetic black pigment, the magnetic black pigment being included in an amount of about 0.1 to about 20 wt %, based on the total weight of the paste composition.

2. The paste composition as claimed in claim 1, wherein the magnetic black pigment includes a metal oxide including at least one of iron (Fe), boron (B), samarium (Sm), and neodymium (Nd).

3. The paste composition as claimed in claim 2, wherein the black pigment further includes a second metal oxide, the second metal oxide including at least one of cobalt (Co), manganese (Mn), chromium (Cr), copper (Cu), aluminum (Al), nickel (Ni), zinc (Zn), ruthenium (Ru), and rhodium (Rh).

4. The paste composition as claimed in claim 1, wherein the conductive material is included in an amount of about 30 to about 90 wt %, the glass frit is included in an amount of about 1 to about 20 wt %, and the organic binder is included in an amount of about 1 to about 20 wt %, based on the total weight of the paste composition.

5. The paste composition as claimed in claim 1, wherein:
the conductive material includes at least one of gold (Au), silver (Ag), copper (Cu), nickel (Ni), palladium (Pd), platinum (Pt), aluminum (Al), and alloys thereof, and
the organic binder includes at least one of an acrylic polymer and a cellulose polymer.

6. The paste composition as claimed in claim 1, further comprising about 1 to about 20 parts by weight of a photo-polymerizable compound and about 0.1 to about 10 parts by weight of a photo-polymerization initiator, based on 100 parts by weight of the paste composition.

7. The paste composition as claimed in claim 1, further comprising an additive including at least one of a UV stabilizer, a viscosity stabilizer, a defoamer, a disperser, a leveling agent, an antioxidant agent, and a thermo-polymerization inhibitor.

8. A method of fabricating an electrode, comprising:
depositing or printing the paste composition as claimed in claim 1 on a glass substrate;
positioning the glass substrate on a magnet substrate; and
drying the paste composition.

9. The method as claimed in claim 8, further comprising forming an electrode pattern by photolithographically developing the dried paste composition.

10. The method as claimed in claim 9, wherein the paste composition is deposited on the glass substrate at a thickness of about 5 to about 40 μm.

11. The method as claimed in claim 8, wherein the drying the paste composition is performed at about 80 to about 150° C. for about 20 to about 60 minutes.

12. The method as claimed in claim 8, further comprising firing the paste composition after drying, wherein the firing the paste composition is performed at about 500 to about 600° C.

13. A plasma display panel, comprising:
an electrode fabricated by the method as claimed in claim 8.

14. A plasma display panel, comprising:
an electrode including a conductive material, a black pigment, and a glass frit, wherein the black pigment includes a magnetic black pigment.

15. The plasma display panel as claimed in claim 14, wherein the magnetic black pigment includes a metal oxide including at least one of iron (Fe), boron (B), samarium (Sm), and neodymium (Nd).

16. The plasma display panel as claimed in claim 15, wherein the black pigment further includes a second metal oxide, the second metal oxide including at least one of cobalt (Co), manganese (Mn), chromium (Cr), copper (Cu), aluminum (Al), nickel (Ni), zinc (Zn), ruthenium (Ru), and rhodium (Rh).

17. The plasma display panel as claimed in claim 14, further comprising a substrate, wherein the electrode has a monolithic structure having an upper portion and a lower portion, the lower portion being adjacent to the substrate and including a greater proportion of magnetic black pigment, relative to the conductive material, than the upper portion.
